(19) United States
(12) Patent Application Publication
(10) Pub. No.: US 2026/0309750 A1
(43) Pub. Date: Oct. 8, 2026

(54) MULTI-PROBER CARTRIDGE

(71) Applicant: KOREA INSTITUTE OF INDUSTRIAL TECHNOLOGY, Cheonan-si (KR)

(72) Inventors: SUNGWON CHOO, Suwon-si (KR); Kyung Tae Nam, Incheon (KR); Seung Kee Mo, Seosan-si (KR)

(21) Appl. No.: 19/313,559

(22) Filed: Aug. 28, 2025

(30) Foreign Application Priority Data
Dec. 16, 2024 (KR) 10-2024-0187456

(51) Int. Cl. G01R 1/073

(52) U.S. Cl. CPC G01R 1/07314; G01R 1/07364

(57) ABSTRACT

According to one aspect of the present disclosure, the multi-prober cartridge includes: a probe card including a main circuit board electrically connected to a plurality of probes, and an edge frame supporting an edge region of the main circuit board; a wafer chuck supporting a wafer that contacts the plurality of probes; and a coupling auxiliary structure coupled to the probe card so as to be coupled to the wafer chuck to couple the probe card to the wafer chuck. The coupling auxiliary structure includes: a base plate supporting one surface of the edge frame; a coupling member having one side fixed to the base plate and the other side pressing the other surface of the edge frame to couple the probe card to the base plate; and an electromagnet part fixed to the base plate and magnetically engageable with a chuck electromagnet part fixed to the wafer chuck.

### CROSS-REFERENCE TO RELATED APPLICATION

The present application claims priority under 35 U.S.C. § 119(a) to Korean patent application number 10-2024-0187456 filed on Dec. 16, 2024, in the Korean Intellectual Property Office, the entire disclosure of which is incorporated by reference herein.

### BACKGROUND

### 1. Technical Field

The present disclosure relates to a multi-prober cartridge.

### 2. Related Art

In general, systems for inspecting semiconductor wafers (hereinafter referred to as “wafers”) are known to employ either a single-prober method or a multi-prober method.

The single-prober method is a method of electrically testing one wafer at a time, in which a single probe card is fixed onto a stage, and then a plurality of wafers are fed onto the stage one by one to perform a testing process.

In contrast, the multi-prober method, unlike the single-prober method in which wafers are tested one by one using probes of a probe card, involves cartridge-forming the probe card and the wafer, loading a plurality of such cartridges into multi-stage channels of an inspection apparatus individually, and then simultaneously testing multiple wafers at once.

However, in the case of the multi-prober method, in the process of cartridge-forming by coupling the probe card and a wafer chuck on which the wafer is placed, it is necessary to modify the structure of the probe card or to install a separate coupling structure on the probe card.

Modifying the structure of the probe card requires significant time and cost, and furthermore, cooperation from the probe card manufacturer is necessary. Moreover, when a separate coupling structure is installed on the probe card, it may cause minute changes to internal connection circuits of the probe card, resulting in performance degradation of the probe card.

In particular, with the recent explosive growth in demand for memory driven by artificial intelligence (AI), virtual reality, and the like, inspections of wafer devices such as high bandwidth memory (HBM) and chiplets have become more challenging, making the structural deformation and stiffness of probe cards increasingly critical.

Accordingly, there is an urgent need for the development of technology that enables a probe card to be used in both the single-prober method and the multi-prober method without structural deformation.

### SUMMARY

The present disclosure is to solve the above problems, and the present disclosure is directed to providing a multi-prober cartridge including a coupling auxiliary structure that can be coupled to a wafer chuck in a state of being coupled to a probe card, without structural deformation causing performance degradation of the probe card in the process of manufacturing the multi-prober cartridge with the probe card.

The problems of the present disclosure are not limited to those mentioned above, and other problems not mentioned will be clearly understood by those of ordinary skill in the art from the following description.

According to one aspect of the present disclosure, provided is a multi-prober cartridge, including a probe card comprising a plurality of probes, a main circuit board electrically connected to the plurality of probes, and an edge frame extending in a lateral direction of the main circuit board and supporting an edge region of the main circuit board; a wafer chuck supporting a wafer that contacts the plurality of probes; and a coupling auxiliary structure coupled to the probe card and configured to be coupled to the wafer chuck to couple the probe card to the wafer chuck, wherein the coupling auxiliary structure includes a base plate supporting one surface of the edge frame; a coupling member having one side fixed to the base plate and the other side pressing the other surface of the edge frame to couple the probe card to the base plate; and an electromagnet part fixed to the base plate and magnetically engageable with a chuck electromagnet part fixed to the wafer chuck.

In this case, the electromagnet part may be provided in plurality, and the plurality of electromagnet parts may be distributed on the base plate.

Meanwhile, the electromagnet part and the chuck electromagnet part each may include an electromagnet or a magnetic material, and at least one of the electromagnet part and the chuck electromagnet part may include an electromagnet.

Meanwhile, a through hole may be formed in a central region of the base plate, and one surface of the edge frame may be supported by an inner edge portion of the base plate formed by the through hole.

Meanwhile, the base plate may include a first base plate having a first seating groove in which one surface of the edge frame is seated; and a second base plate having a second seating groove in which one surface of the first base plate is seated.

Meanwhile, the coupling member may be provided in plurality, and the plurality of coupling members may be distributed on the base plate.

Meanwhile, the multi-prober cartridge may further include a limiter configured to prevent a pressure greater than a set value from being applied to the plurality of probes in contact with the wafer, and the limiter may be either configured to be fixed to the base plate and extending toward the wafer chuck by a predetermined length so as to contact the wafer chuck before a pressure greater than a set value is applied to the plurality of probes, thereby preventing the base plate and the wafer chuck from coming closer together; or configured to be fixed to the wafer chuck and extending toward the base plate by a predetermined length so as to contact the base plate before a pressure greater than a set value is applied to the plurality of probes, thereby preventing the base plate and the wafer chuck from coming closer together.

In this case, the limiter may be provided in plurality, and the plurality of limiters may be distributed on the base plate or the wafer chuck.

Meanwhile, the multi-prober cartridge may further include a plurality of actuators fixed to the base plate or the wafer chuck and configured to extend and contract to adjust a gap between the base plate and the wafer chuck.

In this case, the actuator may be provided in plurality, and the plurality of actuators may be distributed on the base plate.

Meanwhile, the wafer chuck may include a chuck body supporting the wafer; and a chuck bracket having an inner end supported by the chuck body and an outer end extending in a lateral direction of the chuck body, and the chuck electromagnet part may be fixed to the chuck bracket.

According to another aspect of the present disclosure, provided is a multi-prober cartridge, including a probe card comprising a plurality of probes, a main circuit board electrically connected to the plurality of probes, and a central frame supporting a central region of the main circuit board; a wafer chuck on which a wafer in contact with the plurality of probes is supported; and a coupling auxiliary structure coupled to the probe card and configured to be coupled to the wafer chuck to couple the probe card to the wafer chuck, wherein the coupling auxiliary structure includes a bridge plate comprising a bridge part fixed to the central frame and a plate part connected to the bridge part and extending in a lateral direction of the probe card; a base plate supporting one surface of the plate part; a coupling member having one side fixed to the base plate and the other side pressing the other surface of the plate part to couple the probe card to the base plate; and an electromagnet part supported by the base plate and magnetically engageable with a chuck electromagnet part supported by the wafer chuck.

In this case, the electromagnet part may be provided in plurality, and the plurality of electromagnet parts may be distributed on the base plate.

Meanwhile, the coupling member may be provided in plurality, and the plurality of coupling members may be distributed on the base plate.

Meanwhile, the multi-prober cartridge may further include a limiter configured to prevent a pressure greater than a set value from being applied to the plurality of probes in contact with the wafer, and the limiter may be either configured to be fixed to the base plate and extending toward the wafer chuck by a predetermined length so as to contact the wafer chuck before a pressure greater than a set value is applied to the plurality of probes, thereby preventing the base plate and the wafer chuck from coming closer together; or configured to be fixed to the wafer chuck and extending toward the base plate by a predetermined length so as to contact the base plate before a pressure greater than a set value is applied to the plurality of probes, thereby preventing the base plate and the wafer chuck from coming closer together.

Meanwhile, the multi-prober cartridge may further include an actuator fixed to the base plate or the wafer chuck and configured to extend and contract to adjust a gap between the base plate and the wafer chuck.

According to still another aspect of the present disclosure, provided is a multi-prober cartridge, including a probe card comprising a plurality of probes, a main circuit board electrically connected to the plurality of probes, and a central frame supporting a central region of the main circuit board; a wafer chuck on which a wafer in contact with the plurality of probes is supported; and a coupling auxiliary structure coupled to the probe card and configured to be coupled to the wafer chuck to couple the probe card to the wafer chuck, wherein the coupling auxiliary structure includes a bridge plate comprising a bridge part fixed to the central frame and a plate part connected to the bridge part and extending in a lateral direction of the probe card; and an electromagnet part supported by the bridge plate and magnetically engageable with a chuck electromagnet part supported by the wafer chuck.

In this case, the electromagnet part may be provided in plurality, and the plurality of electromagnet parts may be distributed on the bridge plate.

Meanwhile, the multi-prober cartridge may further include a limiter configured to prevent a pressure greater than a set value from being applied to the plurality of probes in contact with the wafer, and the limiter may be either configured to be fixed to the bridge plate and extending toward the wafer chuck by a predetermined length so as to contact the wafer chuck before a pressure greater than a set value is applied to the plurality of probes, thereby preventing the bridge plate and the wafer chuck from coming closer together; or configured to be fixed to the wafer chuck and extending toward the bridge plate by a predetermined length so as to contact the bridge plate before a pressure greater than a set value is applied to the plurality of probes, thereby preventing the bridge plate and the wafer chuck from coming closer together.

Meanwhile, the multi-prober cartridge may further include an actuator fixed to the bridge plate or the wafer chuck and configured to extend and contract to adjust a gap between the bridge plate and the wafer chuck.

According to the above configuration, a coupling auxiliary structure, which is a component of a multi-prober cartridge according to one aspect of the present disclosure, couples a probe card to a base plate by having a coupling member press an upper surface of a plate part of a bridge plate fixed to an edge frame of the probe card or to a central frame of the probe card.

In this case, the probe card can maintain its original function without damage to microcircuits, electrical connection structures, or connectors during the process of manufacturing the multi-prober cartridge.

Furthermore, as a component of the multi-prober cartridge, the probe card can effectively and smoothly perform multi-prober-type testing while maintaining its original function. In addition, the probe card, when separated from the coupling auxiliary structure or the multi-prober cartridge, can effectively and smoothly perform single-prober-type testing while maintaining its original function.

Advantageous effects of the present disclosure are not limited to the above-described effects, and should be understood to include all effects that can be inferred from the configuration of the disclosure described in the detailed description or claims of the present disclosure.

### BRIEF DESCRIPTION OF THE DRAWINGS

FIG. 1 is an exploded perspective view of a multi-prober cartridge according to an exemplary embodiment of the present disclosure.

FIG. 2 is a top view of the multi-prober cartridge according to an exemplary embodiment of the present disclosure.

FIG. 3 is a view taken in the direction of the arrow along line A-A of FIG. 2.

FIG. 4 is a view taken in the direction of the arrow along line B-B of FIG. 2.

FIG. 5 is a view taken in the direction of the arrow along line C-C of FIG. 3.

FIG. 6 is a view taken in the direction of the arrow along line D-D of FIG. 3.

FIG. 7 is a view showing a modification of the base plate illustrated in FIG. 3.

FIG. 8 is a view showing a modification of the coupling member illustrated in FIG. 3.

FIG. 9 is a view showing an aligner apparatus for coupling a probe card assembly and a wafer chuck according to an exemplary embodiment of the present disclosure.

FIG. 10 is a top view of the multi-prober cartridge according to another exemplary embodiment of the present disclosure.

FIG. 11 is a view taken in the direction of the arrow along line E-E of FIG. 9.

FIG. 12 is a top view of the multi-prober cartridge according to still another exemplary embodiment of the present disclosure.

FIG. 13 is a view taken in the direction of the arrow along line F-F of FIG. 12.

### DETAILED DESCRIPTION OF THE EMBODIMENTS

Hereinafter, exemplary embodiments of the present disclosure will be described in detail so that those of ordinary skill in the art can readily implement the present disclosure with reference to the accompanying drawings. The present disclosure may be embodied in many different forms and is not limited to the embodiments set forth herein. In the drawings, parts unrelated to the description are omitted for clarity of description of the present disclosure, and throughout the specification, same or similar reference numerals denote same elements.

The words and terms used in the present specification and claims should not be interpreted as being limited to their ordinary or dictionary meanings, but should be construed as having meanings and concepts consistent with the technical spirit of the present disclosure, in accordance with the principle that an inventor may define terms and concepts to best describe their invention.

Accordingly, the embodiments described in the present specification and the configurations shown in the drawings correspond to preferred embodiments of the present disclosure, and do not represent all the technical spirit of the present disclosure, so the configurations may have various examples of equivalent and modification that can replace them at the time of filing the present disclosure.

It should be understood that the terms “comprise or include” or “have” or the like when used in this specification, are intended to describe the presence of stated features, numbers, steps, operations, elements, components and/or a combination thereof but not preclude the possibility of the presence or addition of one or more other features, numbers, steps, operations, elements, components, or a combination thereof.

The presence of an element in/on “front”, “rear”, “upper or above or top” or “lower or below or bottom” of another element includes not only being disposed in/on “front”, “rear”, “upper or above or top” or “lower or below or bottom” directly in contact with other elements, but also cases in which another element being disposed in the middle, unless otherwise specified. In addition, unless otherwise specified, that an element is “connected” to another element includes not only direct connection to each other but also indirect connection to each other.

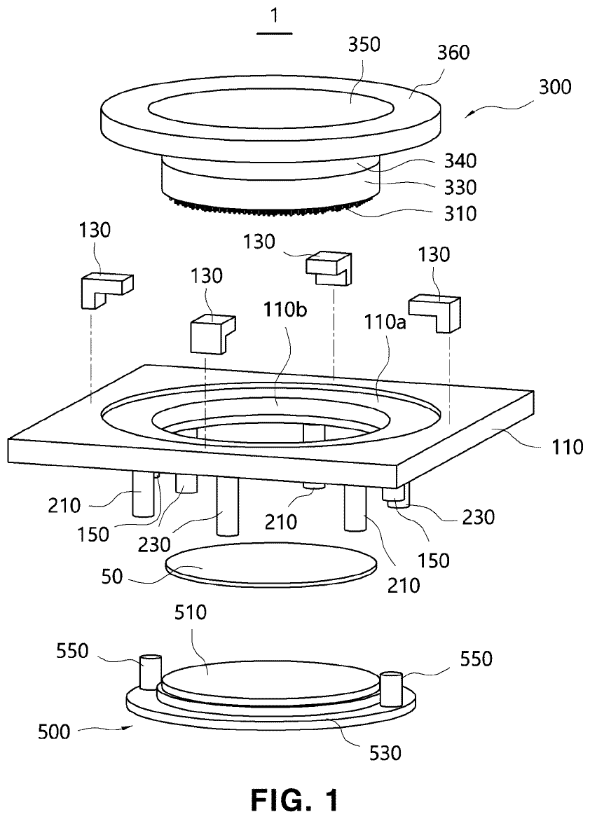

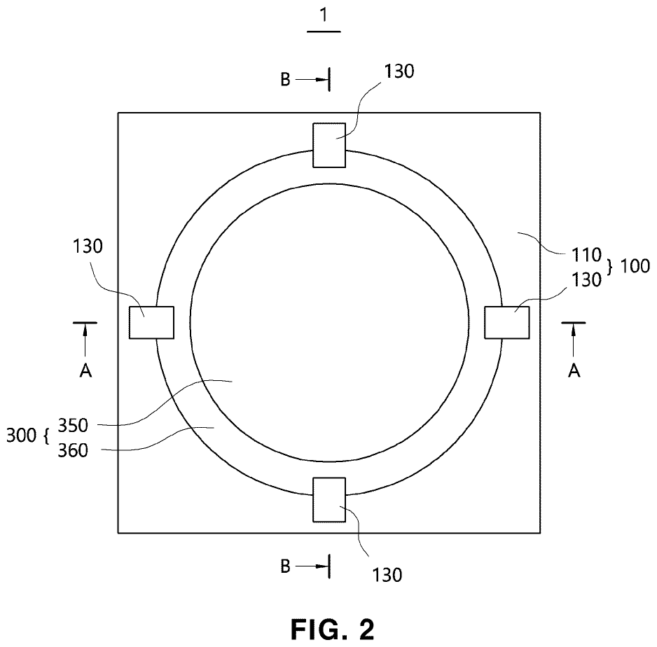

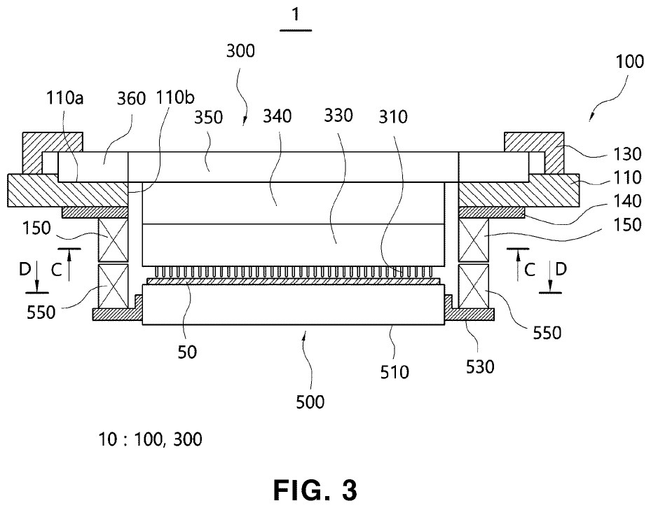

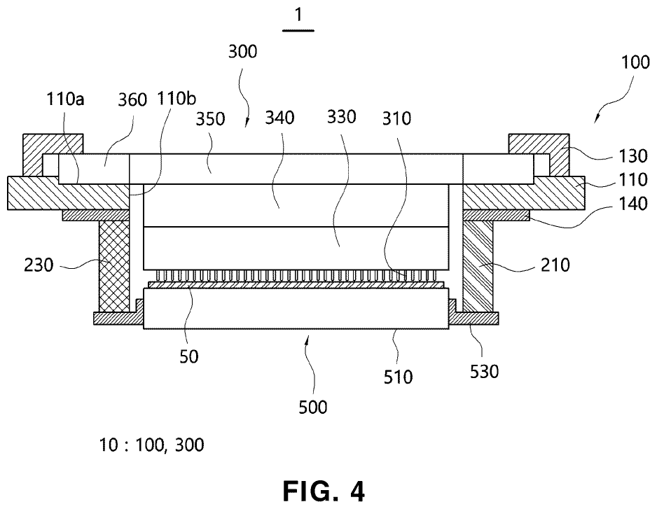

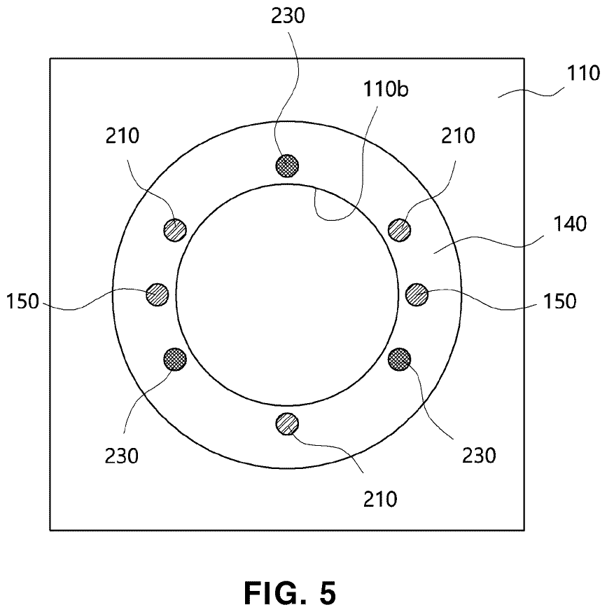

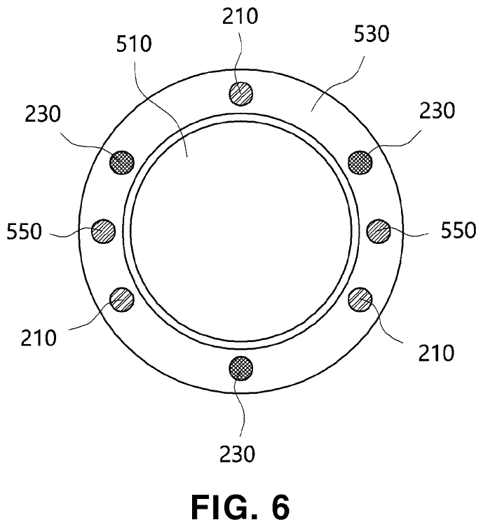

FIG. 1 is an exploded perspective view of a multi-prober cartridge according to an exemplary embodiment of the present disclosure; FIG. 2 is a top view of the multi-prober cartridge according to an exemplary embodiment of the present disclosure; FIG. 3 is a view taken in the direction of the arrow along line A-A of FIG. 2; FIG. 4 is a view taken in the direction of the arrow along line B-B of FIG. 2; FIG. 5 is a view taken in the direction of the arrow along line C-C of FIG. 3; and FIG. 6 is a view taken in the direction of the arrow along line D-D of FIG. 3. For reference, the structure of a probe card 300 is schematically illustrated in FIGS. 1 to 4.

Hereinafter, in FIGS. 1, 3, and 4, a probe card 300 and a wafer chuck 500, which constitute the multi-prober cartridge 1, are disposed vertically and coupled together.

Referring to FIGS. 1 to 6, a multi-prober cartridge 1 according to an exemplary embodiment of the present disclosure includes a coupling auxiliary structure 100, a probe card 300, and a wafer chuck 500.

The coupling auxiliary structure 100 is used to couple the probe card 300 to the wafer chuck 500 that supports a wafer 50.

Specifically, the coupling auxiliary structure 100 is coupled to the wafer chuck 500 in a state in which the coupling auxiliary structure 100 is coupled to the probe card 300. In this case, the probe card 300 may be coupled to the wafer chuck 500 via the coupling auxiliary structure 100 to constitute the multi-prober cartridge 1.

In an exemplary embodiment of the present disclosure, the coupling auxiliary structure 100 is coupled to the probe card 300 without structural deformation that causes changes to microcircuits or an electrical connection state of the probe card 300.

When the coupling auxiliary structure 100 coupled to the probe card 300 is coupled to the wafer chuck 500, the probe card 300 may, as a result, be coupled to the wafer chuck 500 without structural deformation that causes changes to the microcircuits or the electrical connection state.

Accordingly, even when the probe card 300 is coupled to the coupling auxiliary structure 100, the probe card 300 can maintain its original form as manufactured by the manufacturer without structural deformation that causes changes to microcircuits or the like, and no performance degradation of the probe card 300 occurs.

In an exemplary embodiment of the present disclosure, the probe card 300 coupled to the coupling auxiliary structure 100 may be a so-called MEMS probe card manufactured by a MEMS (Micro-Electro-Mechanical-System) method.

In an exemplary embodiment of the present disclosure, the probe card 300 is a probe card having a known structure.

For example, the probe card 300 includes a plurality of probes 310. The probe card 300 also includes a probe substrate 330, an interposer 340, and a main circuit board 350.

The plurality of probes 310 are configured to contact a wafer 50, which will be described later, and protrude from a lower surface of the probe substrate 330. The probe substrate 330 is a ceramic substrate, also referred to as a space transformer (STF).

The probe substrate 330 is electrically connected to the main circuit board 350 by the interposer 340. The main circuit board 350 is connected to a tester (not shown) for testing the performance of a wafer via a connector (not shown).

When the plurality of probes 310 comes into contact with the wafer 50, the wafer 50 is connected to the tester through the plurality of probes 310, the probe substrate 330, the interposer 340, and the main circuit board 350. At this time, the tester analyzes signals exchanged between the wafer 50 and the tester, and based on the analysis, tests the performance of the wafer 50.

In an exemplary embodiment of the present disclosure, the probe card 300 includes an edge frame 360 extending in a lateral direction of the main circuit board 350 and supporting an edge region of the main circuit board 350. However, the probe card 300 may further include frames (not shown) for supporting other portions of the probe card 300 in addition to the edge frame 360.

The edge frame 360 is located farthest in the lateral direction from the center of the probe card 300.

The main circuit board 350 and the edge frame 360 may be formed to have a circular outer contour when viewed from above, as shown in FIG. 1. Alternatively, although not illustrated, the edge frame may be formed to have a polygonal outer contour.

In an exemplary embodiment of the present disclosure, a lower surface of the edge frame 360 of the probe card 300 is supported by a base plate 110 of the coupling auxiliary structure 100, which will be described later.

Since no microcircuits, electrical elements, electrical connection structures, or connectors are disposed on the edge frame 360, deformation of elements, electrical connection structures, or connectors of the probe card 300 can be prevented during the process in which the probe card 300 is supported by the base plate 110.

In an exemplary embodiment of the present disclosure, the coupling auxiliary structure 100 includes a base plate 110, a coupling member 130, and an electromagnet part 150.

The base plate 110 supports a lower surface of the edge frame 360 of the probe card 300.

A through hole 110b is formed in a central region of the base plate 110. The base plate 110 in which the through hole 110b is formed has a ring shape. The base plate 110 may have an inner edge portion and an outer edge portion defined by the through hole 110b.

A lower surface of the edge frame 360 may be supported on an upper surface of the inner edge portion of the base plate 110.

The base plate 110 is formed to have a rectangular outer contour when viewed from above, as shown in FIG. 1, but is not limited thereto.

When the lower surface of the edge frame 360 is supported on the inner edge portion of the base plate 110, a central region of the probe card 300 is disposed to pass through the base plate 110.

The through hole 110b may be formed in a shape corresponding to the shape of the edge frame 360. For example, as shown in FIG. 1, the through hole 110b may be formed in a circular shape corresponding to the circular edge frame 360.

In an exemplary embodiment of the present disclosure, the base plate 110 may be formed with a seating groove 110a. The seating groove 110a may be formed on an upper surface of the inner edge portion of the base plate 110. A lower surface of the edge frame 360 of the probe card 300 may be seated in the seating groove 110a.

An elastic pad (not shown) for elastically supporting the lower surface of the edge frame 360 may be attached to an inner surface of the seating groove 110a.

Referring to FIGS. 3 and 4, the base plate 110 having the seating groove 110a in which the lower surface of the edge frame 360 of the probe card 300 is seated is manufactured in the form of a single member.

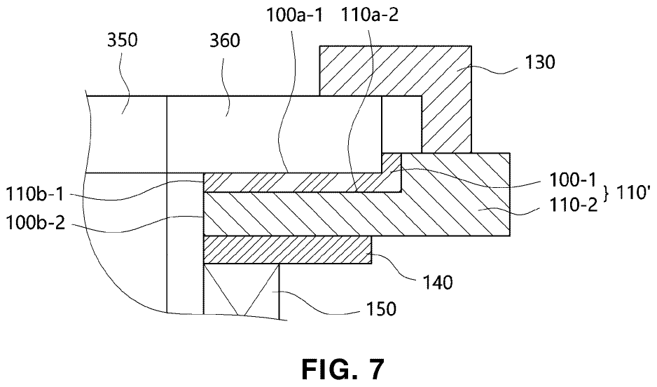

Alternatively, as shown in FIG. 7, the base plate 110′ may include a first base plate 110-1 and a second base plate 110-2 stacked on each other. For reference, FIG. 7 is a view showing a modification of the base plate illustrated in FIG. 3.

Referring to FIG. 7, the first base plate 110-1 supports the edge frame 360 of the probe card 300.

A first through hole 110b-1 is formed in a central region of the first base plate 110-1. In a state in which a central region of the probe card 300 passes through the first through hole 110b-1, a lower surface of the edge frame 360 is supported on an upper surface of the first base plate 110-1.

In this case, an upper surface of the first base plate 110-1 may be formed with a first seating groove 110a-1 in which a lower surface of the first base plate 110-1 is seated. An elastic pad (not shown) for elastically supporting the lower surface of the edge frame 360 may be attached to an inner surface of the first seating groove 110a-1.

The second base plate 110-2 supports the first base plate 110-1. A second through hole 110b-2 is formed in a central region of the second base plate 110-2. A lower surface of the first base plate 110-1 may be supported on an upper surface of an inner edge portion of the second base plate 110-2.

In this case, an upper surface of an inner edge portion of the second base plate 110-2 may be formed with a second seating groove 110a-2 in which a lower surface of the first base plate 110-1 is seated. An elastic pad (not shown) for elastically supporting the lower surface of the first base plate 110-1 may be attached to an inner surface of the second seating groove 110a-2.

The first through hole 110b-1 and the second through hole 110b-2 are connected to each other, and a central region of the probe card 300 is disposed to pass through the first through hole 110b-1 and the second through hole 110b-2.

The first seating groove 110a-1 of the first base plate 110-1 may be formed to correspond to the edge frame 360 of the probe card 300.

In this regard, known probe cards may have various sizes and shapes. In addition, known probe cards may have edge frames of various sizes and shapes.

If the base plate 110 has the form of a single member as shown in FIG. 3, there is a problem in that the entire base plate 110 must be newly manufactured to correspond to probe cards having various sizes and shapes.

To solve this problem, as shown in FIG. 7, the base plate 110 may be configured to include the first base plate 110-1 and the second base plate 110-2. In this case, only the first seating groove 110a-1 may be machined to correspond to the size and shape of the probe card 300 or the edge frame 360, and the remaining portion of the first base plate 110-1 and the second base plate 110-2 can be used as they are without machining, thereby minimizing the portion that changes according to the size and shape of the probe card 300 or the edge frame 360 and thus being economical.

Referring to FIGS. 1 to 4, the coupling member 130 has one side fixed to the base plate 110 and the other side pressing an upper surface of the edge frame 360 of the probe card 300 to couple the probe card 300 to the base plate 110.

Since no microcircuits, electrical elements, electrical connection structures, or connectors are disposed on the edge frame 360, deformation of the microcircuits, electrical elements, or connectors of the probe card 300 can be prevented.

The coupling member 130 couples the probe card 300 and the base plate 110 by simply pressing the upper surface of the edge frame 360 of the probe card 300 without additionally forming bolt holes or pin holes in the probe card 300. Accordingly, the probe card 300 is not damaged by the coupling between the probe card 300 and the coupling member 130, thereby maintaining the performance of the probe card 300.

The coupling member 130 may be fixedly installed on the base plate 110 by various known methods such as pin coupling, bolt coupling, adhesive coupling, or welded coupling.

The coupling member 130 may be fixed to an upper surface of the base plate 110. The coupling member 130 may be fixed to the upper surface of the base plate 110 so as not to interfere with the edge frame 360 of the probe card 300 supported by the base plate 110.

The coupling member 130 may have various shapes and structures.

For example, the coupling member 130 may include an L-shaped retaining clamp, as shown in FIGS. 1, 3, and 4. Hereinafter, the retaining clamp 130 and the coupling member 130 are denoted by the same reference numeral.

When the edge frame 360 of the probe card 300 is supported on the upper surface of the base plate 110 and one side of the retaining clamp 130 is fixed to the upper surface of the base plate 110 by bolting or welding, the other side of the retaining clamp 130 may press the upper surface of the edge frame 360 of the probe card 300.

A buffer pad (not shown) may be provided on the other side of the retaining clamp 130 that contacts the upper surface of the edge frame 360.

One side of the retaining clamp 130 may be fixed to the base plate 110 by a bolt or other known fastening means. The retaining clamp is not limited to an L shape, but may be a U shape or have various other shapes.

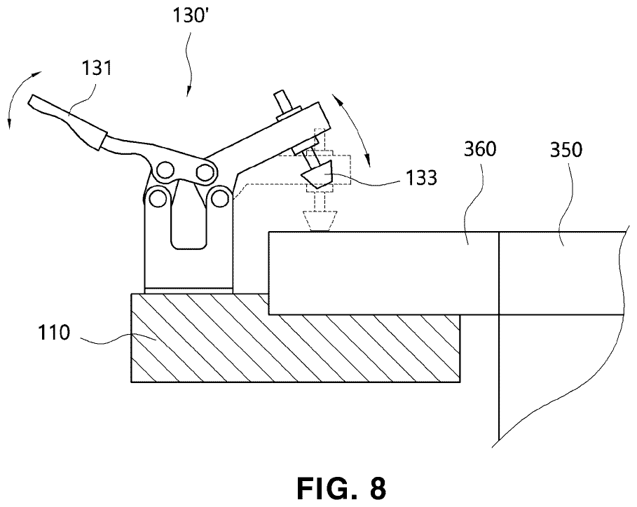

In another example, the coupling member 130′ may include a toggle clamp, as shown in FIG. 8. Hereinafter, the toggle clamp 130′ and the coupling member 130′ are denoted by the same reference numeral. For reference, FIG. 8 is a view showing a modification of the coupling member illustrated in FIG. 3.

After the toggle clamp 130′ is supported on the upper surface of the base plate 110, when a lever 131 of the toggle clamp 130′ rotates in one direction, a pressing portion 133 of the toggle clamp 130′ rotates to press an upper surface of the edge frame 360 of the probe card 300.

In addition, when the lever 131 of the toggle clamp 130′ rotates in the other direction, the pressing portion 133 of the toggle clamp 130′ rotates to be separated from the upper surface of the edge frame 360 of the probe card 300.

In an exemplary embodiment of the present disclosure, with a lower surface of the edge frame 360 supported on the base plate 110, an upper surface of the edge frame 360 is pressed by the coupling member 130. In this case, the base plate 110 can be reliably coupled to the probe card 300.

The coupling member 130 may be provided in plurality. The plurality of coupling members 130 are distributed on the base plate 110.

In this case, the plurality of coupling members 130 may be distributed so that the probe card 300 is stably coupled to the base plate 110. For example, as shown in FIG. 2, the plurality of coupling members 130 may be arranged symmetrically with respect to the center of the base plate 110.

Referring to FIGS. 1, 3, 5, and 6, the electromagnet part 150 is supported on the base plate 110 and is magnetically engageable with a chuck electromagnet part 550 fixed to the wafer chuck 500.

The electromagnet part 150 includes an electromagnet or a magnetic material. And the chuck electromagnet part 550 also includes an electromagnet or a magnetic material.

At this time, at least one of the electromagnet part 150 and the chuck electromagnet part 550 includes an electromagnet. In this case, a timing and coupling strength of engagement between the electromagnet part 150 and the chuck electromagnet part 550 can be adjusted.

The electromagnet part 150 may be supported on a lower surface of the base plate 110.

In this case, the electromagnet part 150 may be fixed to the lower surface of the base plate 110 via a bracket 140. The electromagnet part 150 may be fixed to the bracket 140, and the bracket 140 may be fixed to the lower surface of the base plate 110. The bracket 140 may have a disk shape with a hollow center, but is not limited thereto. However, there is no limitation on the shape or form of the bracket 140.

Alternatively, although not illustrated, the electromagnet part 150 may be directly fixed to a lower surface of the base plate 110 without the bracket 140.

The electromagnet part 150 may be disposed on an inner edge portion of the base plate 110. In this regard, an outer edge portion of the base plate 110 may be supported by an upper plate 1110 of an aligner apparatus 1000, which will be described later. In this case, when the electromagnet part 150 is disposed on the inner edge portion of the base plate 110, it does not interfere with the upper plate 1110 of the aligner apparatus 1000.

The coupling auxiliary structure 100 configured as described above is coupled to the probe card 300 to form a probe card assembly 10, and the electromagnet part 150 of the coupling auxiliary structure 100 is magnetically coupled to the chuck electromagnet part 550 of the wafer chuck 500 to constitute the multi-prober cartridge 1.

In connection with the chuck electromagnet part 550 supported by the wafer chuck 500, the wafer chuck 500 according to an exemplary embodiment of the present disclosure may include a chuck body 510 and a chuck bracket 530.

The chuck body 510 supports the wafer 50. In this case, the wafer 50 is supported on an upper surface of the chuck body 510.

An inner end of the chuck bracket 530 is fixed to the chuck body 510, and an outer end of the chuck bracket 530 extends in a lateral direction of the chuck body 510. The chuck bracket 530 may have a ring shape. The chuck electromagnet part 550 is fixed to an upper surface of the chuck bracket 530.

For example, the chuck bracket 530 and the chuck body 510 may be integrally manufactured by a known casting or injection molding method.

In another example, although not illustrated, the wafer chuck may be manufactured in a form in which the chuck body is laterally extended without the chuck bracket. In this case, the wafer 50 is supported on an upper surface of the chuck body, and the chuck electromagnet part may be fixed to the upper surface of the chuck body so as not to interfere with the wafer 50.

In an exemplary embodiment of the present disclosure, the electromagnet part 150 is provided in plurality. The plurality of electromagnet parts 150 may be disposed on the base plate 110 in a spaced-apart manner. In this case, the plurality of electromagnet parts 150 may have a symmetrical structure with respect to a center of the base plate 110.

In FIGS. 1, 3, and 5, two electromagnet parts 150 are arranged on the base plate 110 in a symmetrical structure with respect to a center of the base plate 110 or a center of the through hole 110b. However, the number of electromagnet parts 150 may be determined according to the shape and size of the base plate. For example, the electromagnet parts 150 may be three in number. In this case, the electromagnet parts 150 may be arranged at intervals of 120 degrees with respect to the center of the base plate 110 or the center of the through hole 110b.

Referring to FIGS. 1, 3, and 6, the number and positions of the chuck electromagnet parts 550 may be determined according to the number of electromagnet parts 150.

After the plurality of probes 310 come into contact with the wafer 50, the electromagnet parts 150 and the chuck electromagnet parts 550 are magnetically coupled with an appropriate magnetic force so that a pressure that does not cause damage to the plurality of probes 310 is applied. In this case, a pressure range that does not cause damage to the plurality of probes 310 and a range of appropriate magnetic force for coupling may be derived by experimental or numerical analysis methods.

When the electromagnet part 150 and the chuck electromagnet part 550 are magnetically coupled, a lower end of the electromagnet part 150 and an upper end of the chuck electromagnet part 550 are spaced apart from each other without contact. The electromagnet part 150 and the chuck electromagnet part 550 have appropriate lengths so that, when magnetically coupled to each other, they maintain a spaced-apart state.

Referring to FIGS. 1, 4, 5, and 6, the multi-prober cartridge 1 according to an exemplary embodiment of the present disclosure may further include a limiter 210.

In this embodiment, the limiter 210 has an upper end fixed to the base plate 110 and a lower end formed to be contactable with the wafer chuck 500. The limiter 210 prevents a pressure exceeding a set value from being applied to the plurality of probes 310 when they are in contact with the wafer 50.

In this regard, after the plurality of probes 310 come into contact with the wafer 50, if excessive magnetic force is applied between the electromagnet part 150 and the chuck electromagnet part 550 due to a failure or malfunction, at least some of the plurality of probes 310 may be damaged by excessive pressure.

To prevent such damage to at least some of the plurality of probes 310, the limiter 210 is used.

The limiter 210 may have a column shape and may be a rigid body having a predetermined rigidity.

For example, when an appropriate magnetic force is generated between the electromagnet part 150 and the chuck electromagnet part 550, a lower end of the limiter 210, whose upper end is fixed to the base plate 110, does not contact the wafer chuck 500.

However, when excessive magnetic force is generated between the electromagnet part 150 and the chuck electromagnet part 550, the lower end of the limiter 210, whose one end is fixed to the base plate 110, comes into contact with the wafer chuck 500. Thereafter, the limiter 210 is not compressed even by the excessive magnetic force between the electromagnet part 150 and the chuck electromagnet part 550, thereby preventing pressure exceeding a set value from being applied to the base plate 110.

The limiter 210 may be disposed on an inner edge portion of the base plate 110. In this case, the limiter 210 does not interfere with an upper plate that supports an outer edge portion of the base plate 110.

The limiter 210 may be provided in plurality. The plurality of limiters 210 may be disposed on the base plate 110 in a spaced-apart manner. In this case, the plurality of limiters 210 may be arranged in a symmetrical structure with respect to a center of the base plate 110 or a center of the through hole 110b. In this case, the plurality of limiters 210 can protect the entirety of the plurality of probes 310 in an even and stable manner.

Alternatively, the limiter 210 may have a lower end fixed to the wafer chuck 500 and an upper end formed to be contactable with the base plate 110.

The multi-prober cartridge 1 according to an exemplary embodiment of the present disclosure may further include a plurality of actuators 230 for adjusting a gap between the probe card 300 and the wafer chuck 500.

In an embodiment of the present disclosure, each of the plurality of actuators 230 has an upper end fixed to the base plate 110 and a lower end extendable and retractable toward the wafer chuck 500. The gap between the base plate 110 and the wafer chuck 500 is adjusted according to an extension length of the plurality of actuators 230.

The plurality of actuators 230 adjust the gap between the base plate 110 and the wafer chuck 500 so that all of the plurality of probes 310 of the probe card 300 are brought into contact with the wafer 50.

For example, in a process in which the wafer chuck 500 is coupled to the coupling auxiliary structure 100 coupled to the probe card 300, the plurality of actuators 230, each extended to a predetermined length in consideration of the contact between the plurality of probes 310 and the wafer 50, may all come into contact with the wafer chuck 500.

In this case, it is preferable that all of the plurality of probes 310 come into contact with the wafer 50.

However, if some of the plurality of probes 310 do not come into contact with the wafer 50, the extension length of at least some of the plurality of actuators 230 may be adjusted so that all of the plurality of probes 310 come into contact with the wafer 50.

The plurality of actuators 230 are distributed on the base plate 110. In this case, the plurality of actuators 230 may be arranged in a symmetrical structure with respect to a center of the base plate 110 or a center of the through hole 110b. In this case, the plurality of actuators 230 can adjust the gap between the base plate 110 and the wafer chuck 500 in a balanced manner.

The actuator 230 may include a piezo actuator. In this case, fine adjustment of the gap between the base plate 110 and the wafer chuck 500 is possible.

Alternatively, the actuator 230 may be a hydraulic cylinder, a pneumatic cylinder, or a known actuator capable of extension and retraction.

Alternatively, the actuator 230 may have a lower end fixed to the wafer chuck 500 and an upper end formed to be contactable with the base plate 110.

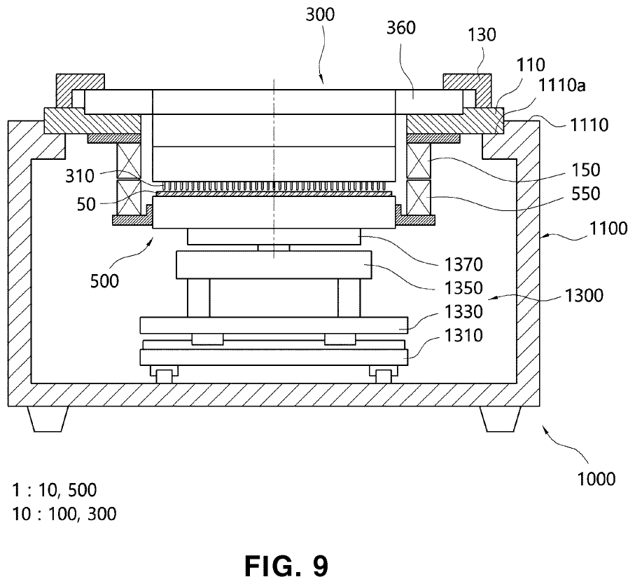

FIG. 9 is a view showing an aligner apparatus for coupling a probe card assembly and a wafer chuck according to an exemplary embodiment of the present disclosure.

Referring to FIG. 9, the aligner apparatus 1000 includes a housing 1100 and a position adjuster 1300.

The housing 1100 includes an upper plate 1110 that supports an outer edge portion of the base plate 110 of the coupling auxiliary structure 100. The upper plate 1110 is formed with a seating groove 1110a in which the outer edge portion of the base plate 110 is seated and supported.

The position adjuster 1300 is disposed inside the housing 1100.

An upper portion of the position adjuster 1300 supports the wafer chuck 500. A wafer 50 to be inspected is supported on an upper surface of the wafer chuck 500.

The position adjuster 1300 may adjust the position of the wafer chuck 500 in forward/backward, left/right, and up/down directions.

For example, the position adjuster 1300 may include a forward/backward movement module 1310 that moves forward and backward, a left/right movement module 1330 that moves left and right, and an up/down movement module 1350 that moves up and down. The forward/backward movement module 1310, the left/right movement module 1330, and the up/down movement module 1350 are coupled to each other to be movable relative to one another.

In FIG. 9, the up/down movement module 1350 is disposed close to the wafer chuck 500. However, this is merely an example, and there is no limitation on the arrangement order of the forward/backward movement module 1310, the left/right movement module 1330, and the up/down movement module 1350. Furthermore, the position adjuster 1300 may adjust the position by rotating the wafer chuck 500 about a rotation axis extending in a vertical direction. To this end, the position adjuster 1300 may include a rotation module 1370 that rotates about the rotation axis extending in a vertical direction.

In FIG. 9, the rotation module 1370 supports the wafer chuck 500 and is rotatably coupled to the up/down movement module 1350. However, this is merely an example, and there is no limitation on the forward/backward movement module 1310, the left/right movement module 1330, the up/down movement module 1350, and the rotation module 1370.

A controller (not shown) controls the forward/backward movement module 1310, the left/right movement module 1330, the up/down movement module 1350, and the rotation module 1370 to adjust the position of the wafer chuck 500.

For example, when a reference mark (not shown) indicated on the probe card 300 or the probe card assembly 10 is captured by a camera (not shown), the controller, based on the captured image information, controls the forward/backward movement module 1310, the left/right movement module 1330, the up/down movement module 1350, and the rotation module 1370 so that the wafer chuck 500 supporting the wafer 50 approaches the probe card 300 in a state aligned with the probe card assembly 10.

When the wafer chuck 500 approaches the probe card 300 in a state aligned with the probe card assembly 10 and the plurality of probes 310 come into contact with the wafer 50, magnetic force is generated between the electromagnet part 150 and the chuck electromagnet part 550, thereby coupling the probe card assembly 10 and the wafer chuck 500 to each other.

In this process, the limiter 210 (see FIG. 4) prevents excessive pressure from being applied to the plurality of probes 310, and the actuator 230 (see FIG. 4) adjusts the gap between the base plate 110 and the wafer chuck 500.

The multi-prober cartridge 1, in which the probe card assembly 10 and the wafer chuck 500 are coupled, may be separated from the aligner apparatus 1000 and loaded into one of multiple channels (not shown) of an inspection apparatus (not shown). The multi-prober cartridge 1 may be loaded into the inspection apparatus in a state arranged in a horizontal direction, a vertical direction, or an oblique direction.

The inspection apparatus may simultaneously perform inspection on the plurality of loaded multi-prober cartridges 1.

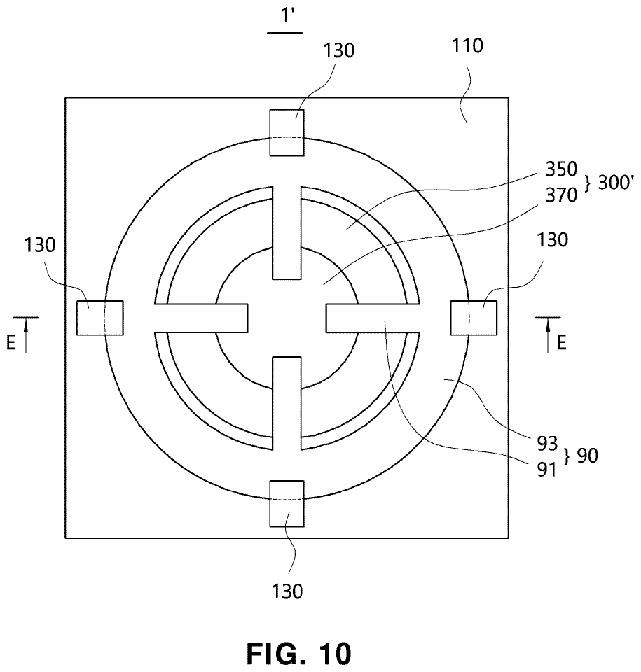

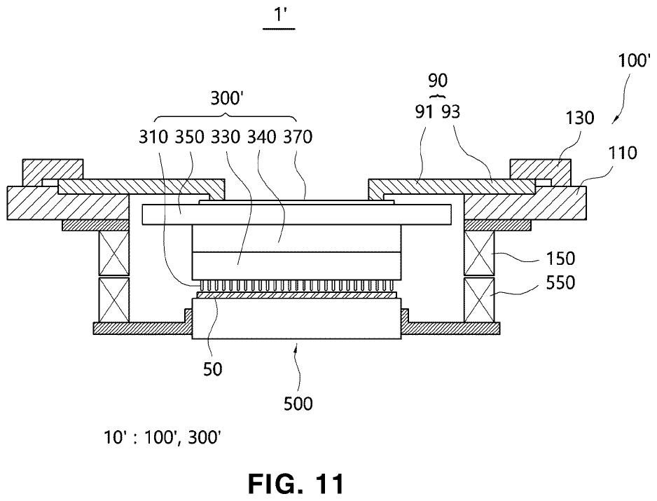

FIG. 10 is a top view of the multi-prober cartridge according to another exemplary embodiment of the present disclosure, and FIG. 11 is a view taken in the direction of the arrow along line E-E of FIG. 9.

Referring to FIGS. 10 and 11, the multi-prober cartridge 1′ according to this embodiment includes a coupling auxiliary structure 100′, a probe card 300′, and a wafer chuck 500. The probe card 300′ according to this embodiment has a structure different from that of the probe card 300 of the previous embodiment, and thus the coupling auxiliary structure 100′ according to this embodiment differs from the coupling auxiliary structure 100 of the previous embodiment.

More specifically, the probe card 300′ according to this embodiment has a structure including a plurality of probes 310, a probe substrate 330, an interposer 340, and a main circuit board 350. And the probe card 300′ further has a structure including a central frame 370 that supports a central region of the main circuit board 350.

However, the probe card 300′ does not include the edge frame 360 of the previous embodiment, which extends in a lateral direction of the main circuit board 350 and supports an edge region of the main circuit board 350. Alternatively, even if the probe card 300′ includes the edge frame 360 of the previous embodiment, it does not have a sufficient area for coupling to the coupling auxiliary structure 100.

If such a probe card 300′ is coupled to the coupling auxiliary structure 100 of the previous embodiment, the lower surface and the upper surface of an edge region of the main circuit board 350 would be supported and pressed instead of the edge frame 360, which may cause damage to microcircuits, electrical connection structures, or connectors of the main circuit board 350.

To address the above problem, the coupling auxiliary structure 100′ according to this embodiment is coupled to the probe card 300′ by utilizing the central frame 370 of the probe card 300′.

More specifically, the coupling auxiliary structure 100′ includes a bridge plate 90, a base plate 110, a coupling member 130, and an electromagnet part 150.

The bridge plate 90 may include a bridge part 91 and a plate part 93.

The bridge part 91 is a portion fixed to the central frame 370 of the probe card 300′. The bridge part 91 may have a bar or rod shape, but is not limited thereto.

The plate part 93 is connected to the bridge part 91 and is formed to extend in a lateral direction of the probe card 300′.

The plate part 93 may have a hollow plate shape. The bridge part 91 is disposed in the hollow of the plate part 93. The hollow of the plate part 93 may have a circular shape, but is not limited thereto.

The plate part 93 may have a disk shape, but is not limited thereto and may have a polygonal plate shape.

An inner end of the bridge part 91 is fixed to the central frame 370, and an outer end of the bridge part 91 is connected to the plate part 93. The bridge part 91 may have a bar shape extending inward from the plate part 93.

The bridge part 91 may be fixed to the central frame 370 by bolts.

The base plate 110 supports a lower surface of the plate part 93 of the bridge plate 90. Except that the object to be supported is the plate part 93 of the bridge plate 90, the base plate 110 is substantially the same as that of the previous embodiment.

The coupling member 130 presses an upper surface of the plate part 93 of the bridge plate 90 to couple the bridge plate 90 to the base plate 110. Except that the object to be pressed is the plate part 93 of the bridge plate 90, the coupling member 130 is the same as in the previous embodiment.

The electromagnet part 150 is supported on the base plate 110 and is magnetically coupled to the chuck electromagnet part 550 supported on the wafer chuck 500. The description of the electromagnet part 150 is replaced with the description provided in the previous embodiment.

The coupling auxiliary structure 100′ configured as described above uses the central frame 370 of the probe card 300′ for coupling, thereby preventing damage to microcircuits, electrical connection structures, or connectors of the probe card 300′ due to the coupling.

It is to be understood that the limiter 210 and the actuator 230 described in the previous embodiment may also be applied to the multi-prober cartridge 1′ according to this embodiment.

The coupling auxiliary structure 100′ according to this embodiment is coupled to the probe card 300′ to form a probe card assembly 10′, and the electromagnet part 150 of the coupling auxiliary structure 100′ is magnetically coupled to the chuck electromagnet part 550 of the wafer chuck 500 to constitute the multi-prober cartridge 1′.

The probe card assembly 10′ and the multi-prober cartridge 1′ according to this embodiment are substantially identical to those of the previous embodiment except that they are coupled using the bridge plate 90 of the coupling auxiliary structure 100′ and the central frame 370 of the probe card 300′, and the features of the respective components described in the previous embodiment are also applicable to this embodiment.

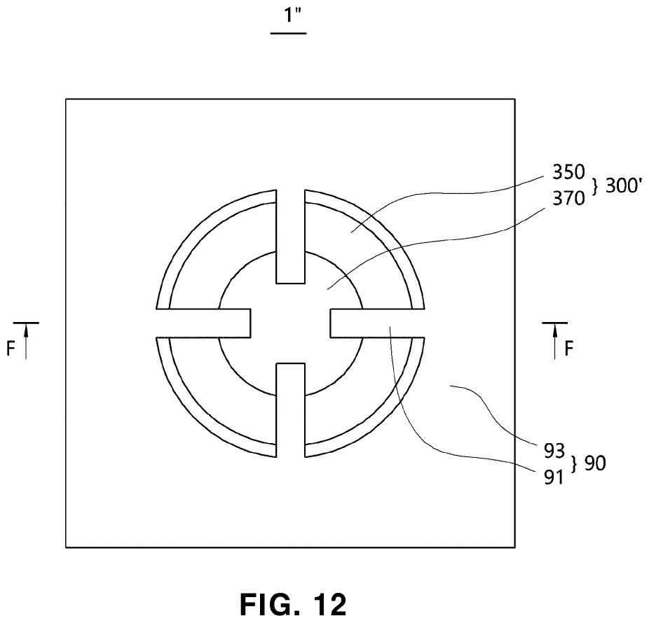

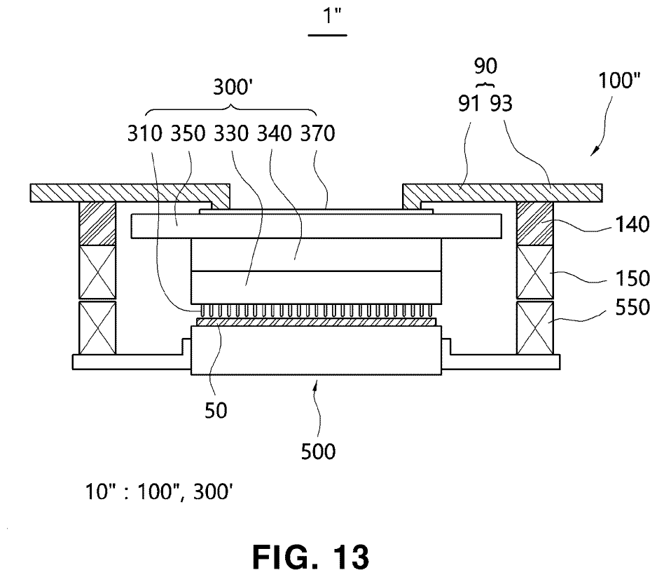

FIG. 12 is a top view of the multi-prober cartridge according to still another exemplary embodiment of the present disclosure, and FIG. 13 is a view taken in the direction of the arrow along line F-F of FIG. 12.

Referring to FIGS. 12 and 13, the multi-prober cartridge 1″ according to this embodiment includes a coupling auxiliary structure 100″, a probe card 300′, and a wafer chuck 500.

The descriptions of the probe card 300′ and the wafer chuck 500 according to this embodiment are replaced with the descriptions of the probe card and the wafer chuck having the same reference numerals in the previous embodiment.

In this embodiment, the coupling auxiliary structure 100″ includes a bridge plate 90 and an electromagnet part 150. The coupling auxiliary structure 100″ differs from the coupling auxiliary structure 100′ of the previous embodiment in that it does not include a base plate 90 (see FIG. 11) and a coupling member 130 (see FIG. 11).

The bridge plate 90 includes a bridge part 91 and a plate part 93.

The bridge part 91 is fixed to the central frame 370 of the probe card 300′, and the plate part 93 is connected to the bridge part 91 and is formed to extend in a lateral direction of the probe card 300′.

The plate part 93 may have a hollow plate shape. The plate part 93 may have a rectangular plate shape, but is not limited thereto, and may have a polygonal plate shape other than a circular or rectangular shape.

An inner end of the bridge part 91 is fixed to the central frame 370, and an outer end of the bridge part 91 is connected to the plate part 93. The bridge part 91 may have a bar shape extending inward from the plate part 93. The bridge part 91 may be fixed to the central frame 370 by bolts.

In this embodiment, the bridge plate 90 is directly supported by an upper plate 1110 (see FIG. 9) of an aligner apparatus 1000 (see FIG. 9).

The electromagnet part 150 is supported by the bridge plate 90 and coupled, by magnetic force, to the chuck electromagnet part 550 supported by the wafer chuck 500. The electromagnet part 150 may be distributed on the bridge plate 90. The remaining description of the electromagnet part 150 is replaced with the description given in the preceding embodiment.

The electromagnet part 150 may be fixed to a lower surface of the bridge plate 90 via a bracket 140. In this case, the bracket 140 may have a plate shape in the form of a ring with a hollow center, but is not limited thereto and may have various shapes and configurations.

Alternatively, although not illustrated, the electromagnet part 150 may be directly fixed to the lower surface of the bridge plate 90 without the bracket 140.

The electromagnet part 150 may be disposed in a partial region of the bridge plate 90 that does not interfere with the probe card 300′ and an upper plate 1110 (see FIG. 9) of an aligner apparatus 1000 (see FIG. 9).

The coupling auxiliary structure 100″ configured as described above, like the coupling auxiliary structure 100′ according to the previous embodiment, is coupled using the central frame 370 of the probe card 300′, thereby preventing damage to microcircuits, electrical connection structures, and connectors of the probe card 300′ caused by the coupling.

Furthermore, the coupling auxiliary structure 100″ according to this embodiment has a simpler structure than the coupling auxiliary structure 100′ according to the previous embodiment, thereby reducing manufacturing costs and facilitating use.

It is to be understood that the limiter 210 and the actuator 230 described in the previous embodiment may also be applied to the multi-prober cartridge 1″ according to this embodiment.

The coupling auxiliary structure 100″ according to this embodiment is coupled to the probe card 300′ to form a probe card assembly 10″, and the electromagnet part 150 of the coupling auxiliary structure 100″ is magnetically coupled to the chuck electromagnet part 550 of the wafer chuck 500 to constitute the multi-prober cartridge 1″.

The probe card assembly 10″ and the multi-prober cartridge 1″ according to this embodiment are substantially identical to the probe card assembly 10′ and the multi-prober cartridge 1′ of the previous embodiment except that they are coupled using the bridge plate 90 of the coupling auxiliary structure 100″ and the central frame 370 of the probe card 300′, and the features of the respective components described in the previous embodiment are also applicable to this embodiment.

In the above-described first two embodiments of the present disclosure, the coupling auxiliary structure 100, 100′ couple the probe card 300, 300′ to the base plate 110 by having the coupling member 130 press the upper surface of the plate part 93 of the bridge plate 90 fixed to the upper surface of the edge frame 360 of the probe card 300 or the central frame 370 of the probe card 300′.

In this case, the probe card 300, 300′ can maintain its original function without damage to microcircuits, electrical connection structures, or connectors during the process of manufacturing the multi-prober cartridge 1, 1′.

Furthermore, in another embodiment of the present disclosure, the coupling auxiliary structure 100″ couples the probe card 300′ to the wafer chuck 500 without the coupling member 130, by coupling the plate part 93 of the bridge plate 90, which is fixed to the central frame 370 of the probe card 300′, to the wafer chuck 500 through magnetic attraction between the electromagnet part 150 and the chuck electromagnet part 550.

In this case, the probe card 300′ may maintain its original function without damage to the microcircuits, electrical connection structures, or connectors during the coupling process in the course of manufacturing the multi-prober cartridge 1″.

Accordingly, as a component of the multi-prober cartridge 1, 1′, 1″, the probe card 300, 300′ can perform multi-prober type testing effectively and smoothly while maintaining its original function.

In addition, the probe card 300, 300′, when separated from the coupling auxiliary structure 100, 100′, 100″ or from the multi-prober cartridge 1, 1′, and 1″, can perform single-prober type testing effectively and smoothly while maintaining its original function.

Although exemplary embodiments of the present disclosure have been described, the spirit of the present disclosure is not limited to the embodiments set forth herein. Those of ordinary skill in the art who understand the spirit of the present disclosure may easily propose other embodiments through supplement, change, removal, addition, etc. of elements within the same scope of spirit, but the embodiments will be also within the scope of the present disclosure.

### DESCRIPTION OF SYMBOLS

1: multi-prober cartridge 10: probe card assembly
50: wafer 90: bridge plate
100, 100′: coupling auxiliary structure
110: base plate 110a: seating groove
110b: through hole 110-1: first base plate
110a-1: first seating groove 110b-1: first through hole
110-2: second base plate 110a-2: second seating groove
110b-2: second through hole 130: coupling member
140: bracket 150: electromagnet part
210: limiter 230: actuator
300, 300′: probe card 310: probe
330: probe substrate 340: interposer
350: main circuit board 360: edge frame
370: central frame 500: wafer chuck
510: chuck body 530: chuck bracket
550: chuck electromagnet part 1000: aligner apparatus
1100: housing 1110: upper plate
1300: position adjuster 1310: forward/backward movement module
1330: left/right movement module
1350: up/down movement module
1370: rotation module

What is claimed is:

1. A multi-prober cartridge, comprising:
a probe card comprising a plurality of probes, a main circuit board electrically connected to the plurality of probes, and an edge frame extending in a lateral direction of the main circuit board and supporting an edge region of the main circuit board;
a wafer chuck supporting a wafer that contacts the plurality of probes; and
a coupling auxiliary structure coupled to the probe card and configured to be coupled to the wafer chuck to couple the probe card to the wafer chuck,
wherein the coupling auxiliary structure comprises:
a base plate supporting one surface of the edge frame;
a coupling member having one side fixed to the base plate and the other side pressing the other surface of the edge frame to couple the probe card to the base plate; and
an electromagnet part fixed to the base plate and magnetically engageable with a chuck electromagnet part fixed to the wafer chuck.

2. The multi-prober cartridge of claim 1,
wherein the electromagnet part is provided in plurality, and
the plurality of electromagnet parts are distributed on the base plate.

3. The multi-prober cartridge of claim 1,
wherein the electromagnet part and the chuck electromagnet part each comprise an electromagnet or a magnetic material, and
at least one of the electromagnet part and the chuck electromagnet part comprises an electromagnet.

4. The multi-prober cartridge of claim 1,
wherein a through hole is formed in a central region of the base plate, and
one surface of the edge frame is supported by an inner edge portion of the base plate formed by the through hole.

5. The multi-prober cartridge of claim 1,
wherein the base plate comprises:
a first base plate having a first seating groove in which one surface of the edge frame is seated; and
a second base plate having a second seating groove in which one surface of the first base plate is seated.

6. The multi-prober cartridge of claim 1,
wherein the coupling member is provided in plurality, and
the plurality of coupling members are distributed on the base plate.

7. The multi-prober cartridge of claim 1,
further comprising a limiter configured to prevent a pressure greater than a set value from being applied to the plurality of probes in contact with the wafer,
wherein the limiter is either:
configured to be fixed to the base plate and extending toward the wafer chuck by a predetermined length so as to contact the wafer chuck before a pressure greater than a set value is applied to the plurality of probes, thereby preventing the base plate and the wafer chuck from coming closer together; or
configured to be fixed to the wafer chuck and extending toward the base plate by a predetermined length so as to contact the base plate before a pressure greater than a set value is applied to the plurality of probes, thereby preventing the base plate and the wafer chuck from coming closer together.

8. The multi-prober cartridge of claim 7,
wherein the limiter is provided in plurality, and
the plurality of limiters are distributed on the base plate or the wafer chuck.

9. The multi-prober cartridge of claim 1, further comprising an actuator fixed to the base plate or the wafer chuck and configured to extend and contract to adjust a gap between the base plate and the wafer chuck.

10. The multi-prober cartridge of claim 9,
wherein the actuator is provided in plurality, and
the plurality of actuators are distributed on the base plate or the wafer chuck.

11. The multi-prober cartridge of claim 1,
wherein the wafer chuck comprises:
a chuck body supporting the wafer; and
a chuck bracket having an inner end supported by the chuck body and an outer end extending in a lateral direction of the chuck body,
and the chuck electromagnet part is fixed to the chuck bracket.

12. A multi-prober cartridge, comprising:
a probe card comprising a plurality of probes, a main circuit board electrically connected to the plurality of probes, and a central frame supporting a central region of the main circuit board;
a wafer chuck on which a wafer in contact with the plurality of probes is supported; and
a coupling auxiliary structure coupled to the probe card and configured to be coupled to the wafer chuck to couple the probe card to the wafer chuck,
wherein the coupling auxiliary structure comprises:
a bridge plate comprising a bridge part fixed to the central frame and a plate part connected to the bridge part and extending in a lateral direction of the probe card;
a base plate supporting one surface of the plate part;
a coupling member having one side fixed to the base plate and the other side pressing the other surface of the plate part to couple the probe card to the base plate; and
an electromagnet part supported by the base plate and magnetically engageable with a chuck electromagnet part supported by the wafer chuck.

13. The multi-prober cartridge of claim 12,
wherein the electromagnet part is provided in plurality, and
the plurality of electromagnet parts are distributed on the base plate.

14. The multi-prober cartridge of claim 12,
wherein the coupling member is provided in plurality, and
the plurality of coupling members are distributed on the base plate.

15. The multi-prober cartridge of claim 12,
further comprising a limiter configured to prevent a pressure greater than a set value from being applied to the plurality of probes in contact with the wafer,
wherein the limiter is either:
configured to be fixed to the base plate and extending toward the wafer chuck by a predetermined length so as to contact the wafer chuck before a pressure greater than a set value is applied to the plurality of probes, thereby preventing the base plate and the wafer chuck from coming closer together; or
configured to be fixed to the wafer chuck and extending toward the base plate by a predetermined length so as to contact the base plate before a pressure greater than a set value is applied to the plurality of probes, thereby preventing the base plate and the wafer chuck from coming closer together.

16. The multi-prober cartridge of claim 12, further comprising an actuator fixed to the base plate or the wafer chuck and configured to extend and contract to adjust a gap between the base plate and the wafer chuck.

17. A multi-prober cartridge, comprising:
a probe card comprising a plurality of probes, a main circuit board electrically connected to the plurality of probes, and a central frame supporting a central region of the main circuit board;
a wafer chuck on which a wafer in contact with the plurality of probes is supported; and
a coupling auxiliary structure coupled to the probe card and configured to be coupled to the wafer chuck to couple the probe card to the wafer chuck,
wherein the coupling auxiliary structure comprises:
a bridge plate comprising a bridge part fixed to the central frame and a plate part connected to the bridge part and extending in a lateral direction of the probe card; and
an electromagnet part supported by the bridge plate and magnetically engageable with a chuck electromagnet part supported by the wafer chuck.

18. The multi-prober cartridge of claim 17,
wherein the electromagnet part is provided in plurality, and
the plurality of electromagnet parts are distributed on the bridge plate.

19. The multi-prober cartridge of claim 17,
further comprising a limiter configured to prevent a pressure greater than a set value from being applied to the plurality of probes in contact with the wafer,
wherein the limiter is either:
configured to be fixed to the bridge plate and extending toward the wafer chuck by a predetermined length so as to contact the wafer chuck before a pressure greater than a set value is applied to the plurality of probes, thereby preventing the bridge plate and the wafer chuck from coming closer together; or
configured to be fixed to the wafer chuck and extending toward the bridge plate by a predetermined length so as to contact the bridge plate before a pressure greater than a set value is applied to the plurality of probes, thereby preventing the bridge plate and the wafer chuck from coming closer together.

20. The multi-prober cartridge of claim 17, further comprising an actuator fixed to the bridge plate or the wafer chuck and configured to extend and contract to adjust a gap between the bridge plate and the wafer chuck.
